(19) United States
(12) Patent Application Publication
(10) Pub. No.: US 2010/0084629 A1
(43) Pub. Date: Apr. 8, 2010

(54) QUANTUM DOT-METAL OXIDE COMPLEX, METHOD OF PREPARING THE SAME, AND LIGHT-EMITTING DEVICE COMPRISING THE SAME

(75) Inventors: Kyoung Soon PARK, Suwon (KR); Bae Kyun Kim, Seongnam (KR); Dong Hyun Cho, Gimhae (KR); In Hyung Lee, Seoul (KR); Jae Il Kim, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/421,215

(22) Filed: Apr. 9, 2009

(30) Foreign Application Priority Data
Oct. 7, 2008 (KR) 10-2008-0098298

(51) Int. Cl. H01L 33/00; H01L 29/15; H01L 21/18

(52) U.S. Cl. 257/13; 257/14; 438/104; 257/E29.072; 257/E33.008; 257/E21.085; 977/774

(57) ABSTRACT

Provided is a quantum dot-metal oxide complex including a quantum dot and a metal oxide forming a 3-dimensional network with the quantum dot. In the quantum dot-metal oxide complex, the quantum dot is optically stable without a change in emission wavelength band and its light-emitting performance is enhanced.

### CROSS-REFERENCE TO RELATED APPLICATIONS

This application claims the priority of Korean Patent Application No. 2008-0098298 filed on Oct. 7, 2008, in the Korean Intellectual Property Office, the disclosure of which is incorporated herein by reference.

### BACKGROUND OF THE INVENTION

1. Field of the Invention

The present invention relates to a quantum dot-metal oxide complex, a method of preparing the same, and a light-emitting device having the same, and more particularly, to a quantum dot-metal oxide complex including a quantum dot that is optically stable without a change in emission wavelength band and has enhanced light-emitting performance, a method of preparing the quantum dot-metal oxide complex, and a light-emitting device including the quantum dot-metal oxide complex.

2. Description of the Related Art

A quantum dot, which is a nano-sized semiconductor material, exhibits the quantum confinement effect. The quantum dot emits stronger light than typical phosphors in a narrow wavelength band. The emission of the quantum dot is generated when excited electrons move from a conduction band to a valence band. Although the quantum dots are formed of the same material, the wavelength of emitted light may vary with a size of the quantum dot. As the size of the quantum dot is smaller, light having a shorter wavelength is emitted. Thus, light having a desired wavelength range can be obtained by adjusting the size of the quantum dot.

The quantum dot emits light even at an arbitrary excitation wavelength. Thus, when several kinds of quantum dots exist, various colored light can be observed at a time even though the quantum dot is excited at a single wavelength. Furthermore, since the quantum dot only moves from a ground vibration state of the conduction band to a ground vibration state of the valence band, the emission wavelength is almost monochromatic light.

As described above, the quantum dot is a nano-sized semiconductor material which is 10 nm or less in diameter. As a method of synthesizing the nanocrystal as the quantum dot, the quantum dot is formed by a vapor deposition method such as a metal organic chemical vapor deposition (MOCVD) and a molecular beam epitaxy (MBE), or a chemical wet method of growing a crystal by putting a precursor material into an organic solvent.

The chemical wet method is a method of controlling the growth of crystals by allowing the organic solvent to be naturally coordinated to a crystal surface of the quantum dot and act as a dispersant. This chemical wet method has the advantage of being capable of controlling the shape and uniformity of nanocrystals through an easy and inexpensive process when compared with the vapor phase deposition methods such as MOCVD and MBE.

The quantum dot prepared through the chemical wet method is not used in its entirety but used with a ligand for the sake of convenience in storage or use. To be specific, as illustrated in FIG. 1, a predetermined ligand 20 is coordinated around a quantum dot 10. Material used for the ligand of the quantum dot is, for example, trioctylphosphine oxide (TOPO).

In the case where the quantum dot coordinated with the ligand 20 is used for a light-emitting device, monochromatic light with a desired wavelength band can be stably emitted by adding an encapsulation material such as a resin. However, in this case, the ligand tends to easily dissolve in or bind with another material. Further, there is still an increasing demand for a light-emitting device with enhanced light-emitting efficiency. Therefore, it is necessary to develop a method of utilizing a quantum dot that is more stable and has enhanced light-emitting performance.

### SUMMARY OF THE INVENTION

An aspect of the present invention provides a quantum dot-metal oxide complex including a quantum dot that is optically stable without a change in emission wavelength band and has enhanced light-emitting performance, a method of preparing the quantum dot-metal oxide complex.

Another aspect of the present invention provides a light-emitting device with enhanced reliability using the quantum dot-metal oxide complex.

According to an aspect of the present invention, there is provided a quantum dot-metal oxide complex including a quantum dot and a metal oxide forming a 3-dimensional network with the quantum dot.

The quantum dot may include a nanocrystal selected from the group consisting of silicon (Si) nanocrystal, group II-VI compound semiconductor nanocrystal, group III-V compound semiconductor nanocrystal, group IV-VI compound semiconductor nanocrystal, and compounds thereof. The group II-VI compound semiconductor nanocrystal may include one selected from the group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe, and HgZnSTe. The group III-V compound semiconductor nanocrystal may include one selected from the group consisting of GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs. The group IV-VI compound semiconductor nanocrystal may include SbTe.

The metal oxide may include one selected from the group consisting of SiO₂, TiO₂, Al₂O₃, and compounds thereof.

According to another aspect of the present invention, there is provided a method of preparing a quantum dot-metal oxide complex with a 3-dimensional network formed, the method including: treating a surface of the quantum dot with amino-alcohol or octylamine modified poly; and reacting the treated quantum dot with a metal oxide. The reacting of the treated quantum dot may include: mixing the treated quantum dot with a metal oxide; and heating a resultant mixture of the quantum dot and the metal oxide.

According to another aspect of the present invention, there is provided a light-emitting device including: a light-emitting source; and a wavelength conversion unit disposed on the light-emitting source in a light-emitting direction and including a quantum dot-metal oxide complex, wherein the quantum dot-metal oxide complex may include a quantum dot emitting light by absorbing light irradiated from the light-emitting source, and a metal oxide forming a 3-dimensional network with the quantum dot. The light-emitting source may include one of a light-emitting diode (LED) and a laser diode.

The wavelength conversion unit may be provided in plurality, and at least two layers of the plurality of wavelength conversion units may include quantum dots which convert the light emitted from the light-emitting source into light having different wavelengths. The light-emitting source may emit a blue light, a first wavelength conversion unit among the plurality of wavelength conversion units may emit a red light, and a second wavelength conversion unit different from the first wavelength conversion unit among the plurality of wavelength conversion units may emit a green light.

The light-emitting device may further include: a groove part having a bottom surface where the light-emitting source is mounted, and a side surface where a reflection part is formed; and a support part supporting the groove part and including a lead frame electrically connected to the light-emitting source. The groove part may be encapsulated with an encapsulation material. The encapsulation material may include at least one of epoxy, silicon, acryl-based polymer, glass, carbonate-based polymer, and a mixture thereof. The wavelength conversion unit may be formed inside the groove part where the light-emitting source is mounted.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates a state that a ligand is coordinated to a surface of a quantum dot in a related art;

FIGS. 2A and 2B illustrate quantum dot-metal oxide complexes according to an embodiment of the present invention;

FIGS. 3A and 3B are states that surfaces of quantum dots are treated with amino-alcohol and octylamine modified poly respectively according to an embodiment of the present invention;

FIG. 4 illustrates a light-emitting device according to an embodiment of the present invention; and

FIG. 5 illustrates a light-emitting device according to another embodiment of the present invention.

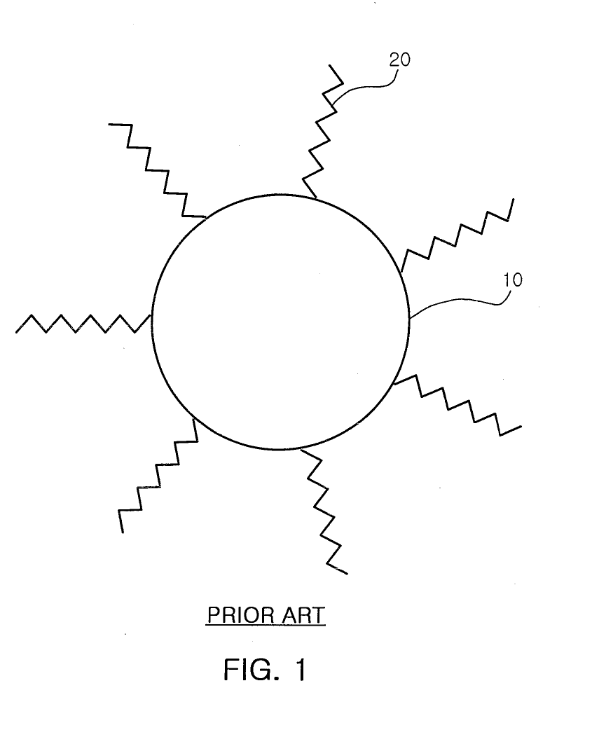

### DETAILED DESCRIPTION OF THE PREFERRED EMBODIMENT

Exemplary embodiments of the present invention will now be described in detail with reference to the accompanying drawings. The present invention may, however, be embodied in many different forms and should not be construed as being limited to the embodiments set forth herein. These embodiments are provided to thoroughly explain the present invention to a person with ordinary skill in the art. Furthermore, it should be noted that elements shown in the accompanying drawings may be scaled up or down for convenience in description.

A quantum dot-metal oxide complex according to the present invention includes a quantum dot and a metal oxide forming a 3-dimensional network with the quantum dot.

The quantum dot is a nano-sized light-emitting body, as described above, and may include a semiconductor nanocrystal. Examples of the quantum dot may include silicon (Si) nanocrystal, group II-VI compound semiconductor nanocrystal, group III-V compound semiconductor nanocrystal, or group IV-VI compound semiconductor nanocrystal. In the present invention, each of the quantum dots may be singly used or a mixture thereof may be used.

The group II-VI compound semiconductor nanocrystal may include, for example, CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe, or HgZnSTe, but is not limited thereto.

The group III-V compound semiconductor nanocrystal may include, for example, GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs, but is not limited thereto. Moreover, the group IV-VI compound semiconductor nanocrystal may include, but is not limited to, SbTe.

The metal oxide forming the 3-dimensional network with the quantum dot may include one selected from the group consisting of SiO₂, TiO₂, Al₂O₃, and compounds thereof, but is not limited thereto.

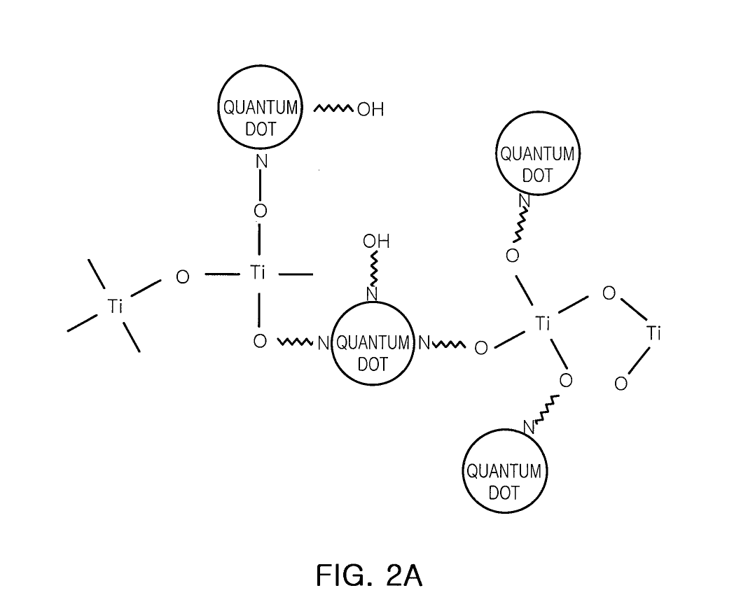

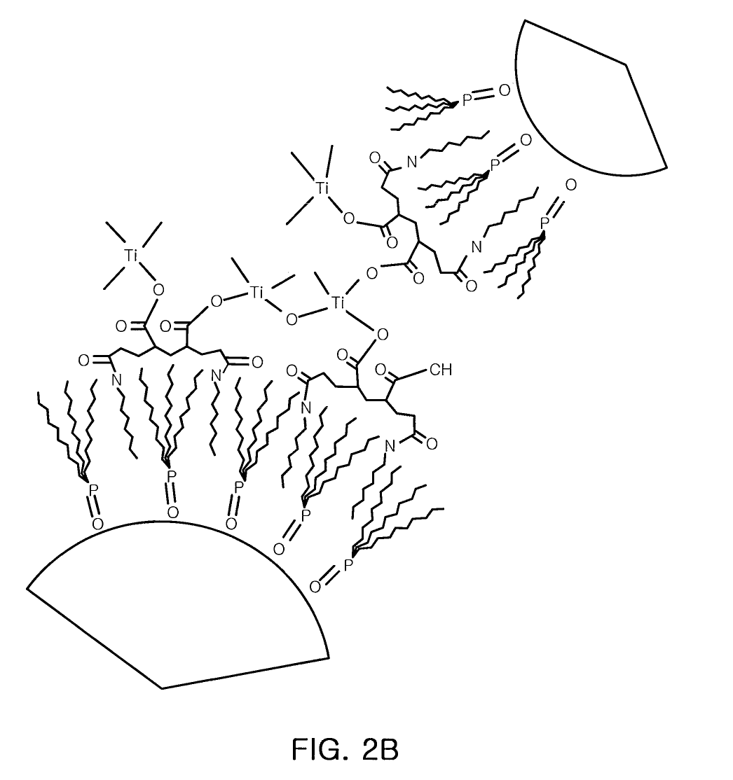

FIG. 2A illustrates a quantum dot-metal oxide complex prepared by using a quantum dot treated with amino-alcohol according to an embodiment of the present invention. The quantum dot and the metal oxide form a 3-dimensional network, as shown in FIG. 2A. Molecules having predetermined functional groups are attached to the quantum dot, and they bind with oxygen of the metal oxide to thereby form the 3-dimensional network.

FIG. 2B illustrates a quantum dot-metal oxide complex prepared by using a quantum dot treated with octylamine modified poly according to another embodiment of the present invention. Here, the octylamine modified poly is PAA with octylamine attached, that is, acrylic acid, but it not limited thereto. Thus, any ligand having a functional group allowing a quantum dot-metal oxide complex to be formed can be used in various forms.

Like FIG. 2A, the quantum dot and the metal oxide also form a 3-dimensional network, as shown in FIG. 2B. Molecules which surround the ligand and have functional groups are attached around the quantum dot, and they bind with oxygen of the metal oxide to thereby form the 3-dimensional network.

As illustrated in FIGS. 2A and 2B, in the case where the 3-dimensional network is formed using the quantum dot-metal oxide complex, the quantum dot is not simply coordinated with the ligand but strongly fixed to the metal oxide. Therefore, the quantum dot, which is made of inorganic material, is surrounded by the metal oxide so that it can be protected from an external environment, thus enhancing optical stability.

A method of preparing a quantum dot-metal oxide complex with a 3-dimensional network formed includes: treating the quantum dot with amino-alcohol or octylamine modified poly; and reacting the treated quantum dot with a metal oxide. Herein, the reacting of the treated quantum dot may include: mixing the treated quantum dot with a metal oxide; and heating a resultant mixture of the quantum dot and the metal oxide.

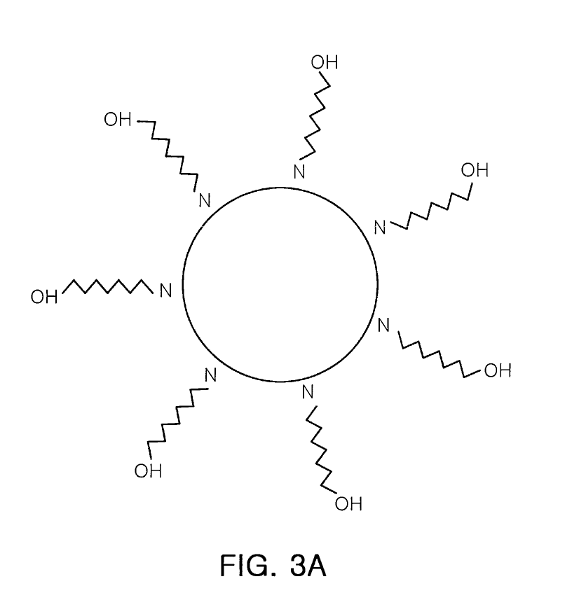

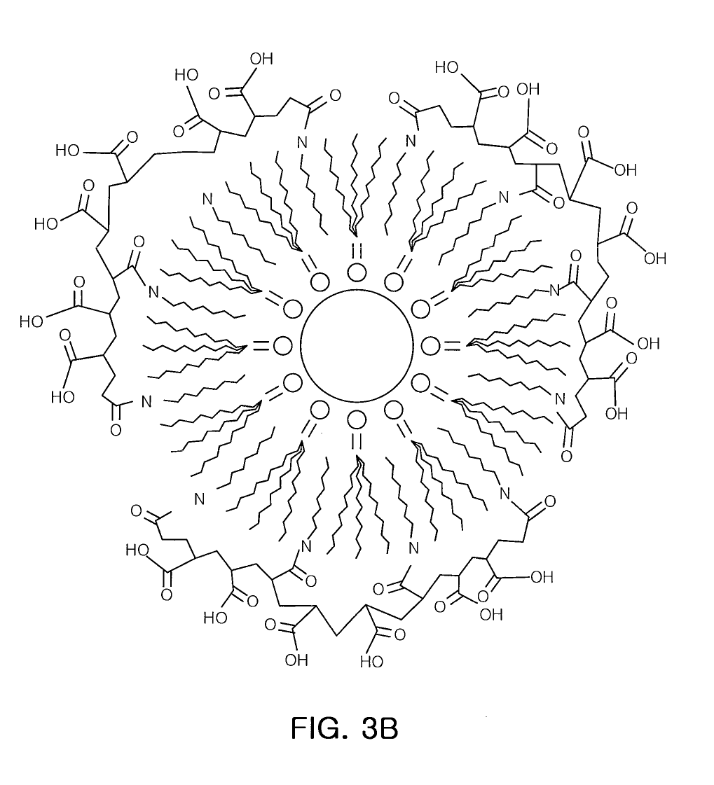

FIGS. 3A and 3B illustrate a bound state that a molecule having a predetermined functional group is located around a quantum dot and binds with a metal oxide.

FIG. 3A illustrates a state that a quantum dot is surface-treated with amino-alcohol according to an embodiment of the present invention. As illustrated in FIG. 3A, instead of a direct bonding between the quantum dot and the metal oxide to form the 3-dimensional network, the ligand of the quantum dot is substituted with a molecule having an amino group and a hydroxyl group through amino-alcohol treatment and then binds with the metal oxide to thereby form the 3-dimensional network shown in FIG. 2A. Here, the amine group is a functional group enhancing optical properties of the quantum dot, and the hydroxyl group is a functional group forming the 3-dimensional network with the metal oxide.

To be specific, the quantum dot is surface-treated with amino-alcohol to prepare a quantum dot-metal oxide complex through the reaction between the quantum dot and the metal oxide. That is, the ligand bound to the quantum dot reacts with a material having the amine group and the hydroxyl group to treat the surface of the quantum dot with amino-alcohol. Accordingly, the amine group is located in the vicinity of the quantum dot and the hydroxyl group is located at an opposite site of the amine group in an external direction of the quantum dot, as shown in FIG. 3A. The surface-treated quantum dot is dissolved into an alcoholic solution such as ethanol.

Thereafter, the quantum dot treated with amino-alcohol is mixed with the metal oxide. A precursor of the metal oxide may employ, for example, Ti (OBu)₄. After mixed with the metal oxide, the mixture of the quantum dot and the metal oxide is heated to form the 3-dimensional network. Finally, the quantum dot-metal oxide complex is achieved.

FIG. 3B illustrates a state that a quantum dot is surface-treated with octylamine modified poly according to an embodiment of the present invention. As illustrated in FIG. 3B, instead of a direct bonding between the quantum dot and the metal oxide to form the 3-dimensional network, the ligand of the quantum dot is surrounded by a molecule having a carboxyl group (R—COOH) and then binds with the metal oxide to thereby form the 3-dimensional network shown in FIG. 2B.

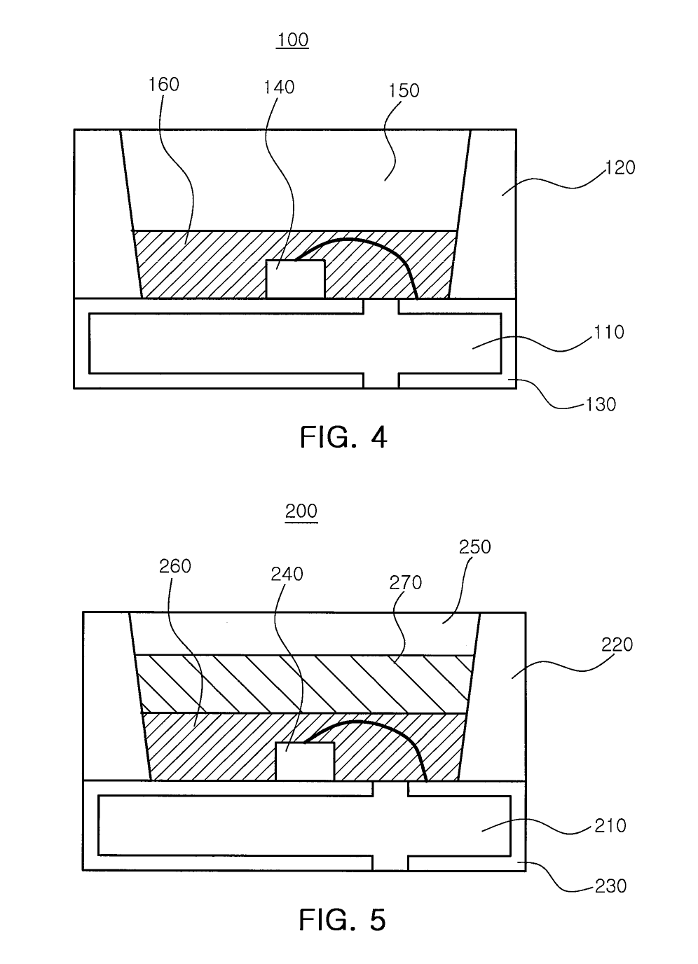

FIG. 4 illustrates a light-emitting device 100 according to an embodiment of the present invention. According to the present invention, the light-emitting device 100 includes: a light-emitting source 140; and a wavelength conversion unit 160 disposed on the light-emitting source 140 in a light-emitting direction. Herein, the wavelength conversion unit 160 includes a quantum dot emitting light by absorbing light irradiated from the light-emitting source, and a metal oxide forming a 3-dimensional network with the quantum dot.

Referring to FIG. 4, the light-emitting device 100 may further include: a groove part having a bottom surface where the light-emitting source 140 is mounted, and a side surface where a reflection part 120 is formed; and a support part 110 supporting the groove part and having a lead frame 130 electrically connected to the light-emitting source 140.

The light-emitting source 140 may include one of a light-emitting diode (LED) and a laser diode. When the light-emitting source 140 is implemented with a blue LED, the blue LED may be a GaN (gallium nitride)-based LED that emits a blue light in a wavelength band of 420 to 480 nm. The lead frame 130, i.e., terminal electrode, on the support part 110 is connected to the light-emitting source 140 through a wire. An encapsulation material 150 fills the groove part over the light-emitting source 140 to encapsulate the light-emitting source 140. The encapsulation material 150 may include at least one of epoxy, silicon, acryl-based polymer, glass, carbonate-based polymer, and a mixture thereof.

After mounting the light-emitting source 140, the wavelength conversion unit 160 is formed on the light-emitting source 140 before the groove part is filled with the encapsulation material 150. The wavelength conversion unit 160 may include a quantum dot-metal oxide complex having an appropriate quantum dot according to the wavelength of light desired to be obtained from the light-emitting source 140.

Although the wavelength conversion unit 160 shown in FIG. 4 is formed in a layer type, it may also be formed to cover the surface of the light-emitting source 140. Also, the wavelength conversion unit 160 may be disposed in any shape only if the light incident from the light-emitting source 140 can be wavelength-converted at the wavelength conversion unit 160.

The light-emitting device 100 can emit a white light when the light-emitting source 140 emits a blue light, the quantum dot in the quantum dot-metal oxide complex of the wavelength conversion unit 160 emits a yellow light.

FIG. 5 illustrates a light-emitting device 200 according to another embodiment of the present invention. The light-emitting device 200 of FIG. 5 is the same as the light-emitting device 100 of FIG. 4 except that a wavelength conversion unit is implemented with two layers 260 and 270. Therefore, a supporter 210, a lead frame 230, a reflection part 220, a light-emitting source 240 and an encapsulation material 250 in FIG. 5 have the same functions as those described in FIG. 4, and thus description for them will be omitted herein.

The wavelength conversion unit of the light-emitting device 200 may be provided in plurality. In FIG. 5, one of the wavelength conversion units closer to the light-emitting source 240 is referred to a first wavelength conversion unit 260, and the other one is referred to as a second wavelength conversion unit 270.

At least two of the plurality of wavelength conversion units may include quantum dots which can convert the light emitted from the light-emitting source 240 into light having different wavelengths. Therefore, the first and second wavelength conversion units 260 and 270 may include quantum dot-metal oxide complexes including quantum dots capable of converting light into light of different wavelength. For example, the light-emitting device can emit a white light when the light-emitting source 240 emits a blue light, the first wavelength conversion unit 260 emits a red light, and the second wavelength conversion unit 270 emits a green light.

While FIG. 5 illustrates that the wavelength conversion unit is implemented with two layers, the wavelength conversion unit can be implemented with three layers. That is, the light-emitting device can emit a white light even when the light-emitting source emits a ultraviolet light, and the three wavelength conversion units emit a blue, green and red light, respectively. In addition, to implement a white light-emitting device, a phosphor can be added to the encapsulation material instead of using a wavelength conversion quantum dot of one color in the wavelength conversion unit, and used together with the wavelength conversion unit including a quantum dot-metal oxide complex.

The light-emitting devices are shown in a package type in FIGS. 4 and 5, but they are not limited thereto. For example, the light-emitting devices may be lamp-type light-emitting devices.

According to the present invention, since the quantum dot forms the stable network with the inorganic material, i.e., metal oxide and is surrounded by the metal oxide in the quantum dot-metal oxide complex, the quantum dot is isolated from an external environment and thus the optical stability is enhanced. Consequently, the light-emitting performance of the quantum dot can be improved.

Furthermore, according to the inventive method of preparing the quantum dot-metal oxide complex, the complex containing the quantum dot can be formed regardless of a size and kind of the quantum dot. Hence, the inventive method can be easily applied to various fields. Moreover, the concentration of quantum dots in the complex is determined by adjusting the concentration of the quantum dots in use, thereby making it possible to form a high-concentration quantum dot complex.

In addition, it is easy to manufacture a white light-emitting device if using the quantum dot-metal oxide complex as the wavelength conversion unit that converts the light emitted from the light-emitting source into light with different wavelengths.

While the present invention has been shown and described in connection with the exemplary embodiments, it will be apparent to those skilled in the art that modifications and variations can be made without departing from the spirit and scope of the invention as defined by the appended claims.

What is claimed is:

1. A quantum dot-metal oxide complex comprising a quantum dot and a metal oxide forming a 3-dimensional network with the quantum dot.

2. The quantum dot-metal oxide complex of claim 1, wherein the quantum dot comprises a nanocrystal selected from the group consisting of silicon (Si) nanocrystal, group II-VI compound semiconductor nanocrystal, group III-V compound semiconductor nanocrystal, group IV-VI compound semiconductor nanocrystal, and compounds thereof.

3. The quantum dot-metal oxide complex of claim 2, wherein the group II-VI compound semiconductor nanocrystal comprises one selected from the group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe, and HgZnSTe.

4. The quantum dot-metal oxide complex of claim 2, wherein the group III-V compound semiconductor nanocrystal comprises one selected from the group consisting of GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs.

5. The quantum dot-metal oxide complex of claim 2, wherein the IV-VI group-based compound semiconductor nanocrystal comprises SbTe.

6. The quantum dot-metal oxide complex of claim 1, wherein the metal oxide comprises one selected from the group consisting of SiO₂, TiO₂, Al₂O₃, and compounds thereof.

7. A method of preparing a quantum dot-metal oxide complex with a 3-dimensional network formed, the method comprising:
treating a surface of the quantum dot with amino-alcohol or octylamine modified poly; and
reacting the treated quantum dot with a metal oxide.

8. The method of claim 7, wherein the reacting of the treated quantum dot comprises:
mixing the treated quantum dot with a metal oxide; and
heating a resultant mixture of the quantum dot and the metal oxide.

9. A light-emitting device comprising:
a light-emitting source; and
a wavelength conversion unit disposed on the light-emitting source in a light-emitting direction and including a quantum dot-metal oxide complex,
wherein the quantum dot-metal oxide complex comprises a quantum dot emitting light by absorbing light irradiated from the light-emitting source, and a metal oxide forming a 3-dimensional network with the quantum dot.

10. The light-emitting device of claim 9, wherein the quantum dot comprises a nanocrystal selected from the group consisting of Si nanocrystal, group II-VI compound semiconductor nanocrystal, group III-V compound semiconductor nanocrystal, group IV-VI compound semiconductor nanocrystal, and compounds thereof.

11. The light-emitting device of claim 9, wherein the group II-VI compound semiconductor nanocrystal comprises one selected from the group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe, and HgZnSTe.

12. The light-emitting device of claim 9, wherein the group III-V compound semiconductor nanocrystal comprises one selected from the group consisting of GaN, GaP, GaAs, AlN, Alp, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs.

13. The light-emitting device of claim 9, wherein the IV-VI group-based compound semiconductor nanocrystal comprises SbTe.

14. The light-emitting device of claim 9, wherein the metal oxide comprises one selected from the group consisting of SiO₂, TiO₂, Al₂O₃, and compounds thereof.

15. The light-emitting device of claim 9, wherein the light-emitting source comprises one of a light-emitting diode (LED) and a laser diode.

16. The light-emitting device of claim 9, wherein the wavelength conversion unit is provided in plurality.

17. The light-emitting device of claim 16, wherein at least two layers of the plurality of wavelength conversion units comprise quantum dots which convert the light emitted from the light-emitting source into light having different wavelengths.

18. The light-emitting device of claim 16, wherein:
the light-emitting source emits a blue light;
a first wavelength conversion unit among the plurality of wavelength conversion units emits a red light; and
a second wavelength conversion unit different from the first wavelength conversion unit among the plurality of wavelength conversion units emits a green light.

19. The light-emitting device of claim 9, further comprising:
a groove part having a bottom surface where the light-emitting source is mounted, and a side surface where a reflection part is formed; and
a support part supporting the groove part and comprising a lead frame electrically connected to the light-emitting source.

20. The light-emitting device of claim 19, wherein the groove part is encapsulated with an encapsulation material.

21. The light-emitting device of claim 20, wherein the encapsulation material comprises at least one of epoxy, silicon, acryl-based polymer, glass, carbonate-based polymer, and a mixture thereof.

22. The light-emitting device of claim 19, wherein the wavelength conversion unit is formed inside the groove part where the light-emitting source is mounted.
